(19) United States
(12) Patent Application Publication
(10) Pub. No.: US 2026/0198160 A1
(43) Pub. Date: Jul. 9, 2026

(54) SUBMOUNT STRUCTURES OF LIGHT-EMITTING DIODES AND RELATED METHODS

(71) Applicant: CreeLED, Inc., Durham, NC (US)

(72) Inventors: Colin Blakely, Raleigh, NC (US); David Suich, Durham, NC (US); Andre Pertuit, Raleigh, NC (US); Joseph G. Sokol, Durham, NC (US); Robert Wilcox, Rolesville, NC (US); Michael Check, Holly Springs, NC (US)

(21) Appl. No.: 19/015,178

(22) Filed: Jan. 9, 2025

(51) Int. Cl. H10H 29/85; H10H 29/01; H10H 29/80; H10W 90/00

(52) U.S. Cl. CPC H10H 29/8508; H10H 29/0364; H10H 29/8506; H10H 29/857; H10H 29/942; H10W 90/00

(57) ABSTRACT

Light-emitting diode (LED) devices and more particularly submount structures in LED devices and related methods are disclosed. Submount structures include submounts with sidewall connectors along perimeter sidewalls that electrically couple chip bonding pads on top submount surfaces to package bonding pads on submount bottom surfaces. LED devices include LED packages, such as chip-scale LED packages, with reduced footprints where electrically conductive paths are provided as one or more metal layers on the perimeter sidewalls. Exemplary methods include various sequences for depositing the sidewall connectors.

### FIELD OF THE DISCLOSURE

The present disclosure relates to light-emitting diode (LED) devices, and more particularly to submount structures in LED devices and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LED packages have been developed that provide mechanical support, electrical connections, and encapsulation for LED emitters. As LED technology continues to be developed for ever-evolving modern applications, challenges exist in keeping up with operating demands for LED devices, particularly as overall LED device sizes continue to be miniaturized.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to submount structures in LED devices and related methods. Submount structures include submounts with sidewall connectors along perimeter sidewalls that electrically couple chip bonding pads on top submount surfaces to package bonding pads on submount bottom surfaces. LED devices include LED packages, such as chip-scale LED packages, with reduced footprints where electrically conductive paths are provided as one or more metal layers on the perimeter sidewalls. Exemplary methods include various sequences for depositing the sidewall connectors.

In one aspect, an LED package comprises: a submount comprising a first surface, a second surface, and a perimeter sidewall extending between the first surface and the second surface; a chip bonding pad on the first surface; an LED chip mounted to the chip bonding pad, the LED chip covering at least 80% of an area of the first surface; a package bonding pad on the second surface; and a sidewall connector electrically coupling the chip bonding pad to the package bonding pad along the perimeter sidewall. In certain embodiments, a lateral width of the LED chip is at least the same as a lateral width of the submount. In certain embodiments, the lateral width of the LED chip is greater than the lateral width of the submount. In certain embodiments, the sidewall connector extends on a side surface of the chip bonding pad and on a side surface of the package bonding pad. In certain embodiments, the sidewall connector comprises a first metal layer on the perimeter sidewall and a second metal layer on the first metal layer. In certain embodiments, the first metal layer comprises a sintered metal and the second metal layer comprises a plated metal. In certain embodiments, the first metal layer comprises a seed layer and the second metal layer comprises a plated metal. The LED package may further comprise a light-altering material on perimeter edges of the LED chip. The LED package may further comprise a wavelength conversion element on the LED chip and on the light-altering material. In certain embodiments, the sidewall connector forms at least one half via along the perimeter sidewall. In certain embodiments, the sidewall connector comprises a first metal layer that extends along the perimeter sidewall and a second metal layer on the first metal layer, wherein the second metal layer extends past the first metal to electrically contact a side surface of the chip bonding pad and a side surface of the package bonding pad. The LED package may further comprise a thermal pad on the second surface of the submount, wherein the thermal pad is electrically isolated from the LED chip.

In another aspect, a method for forming an LED package comprises: providing a submount comprising a first surface, a second surface, and a perimeter sidewall extending between the first surface and the second surface; forming a chip bonding pad on the first surface and a package bonding pad on the second surface; depositing a sidewall connector on the perimeter sidewall, the sidewall connector electrically coupling the chip bonding pad to the package bonding pad along the perimeter sidewall; and attaching an LED chip to the chip bonding pad, the LED chip covering at least 80% of an area of the first surface. In certain embodiments, depositing the sidewall connector comprises depositing a first metal layer on the perimeter sidewall and depositing a second metal layer on the first metal layer. In certain embodiments, depositing the first metal layer comprises dispensing the first metal layer followed by heating the first metal layer to solidify the first metal layer, and wherein depositing the second metal layer comprises plating the second metal layer on the first metal layer. In certain embodiments, depositing the first metal layer comprises depositing the first metal layer as a seed layer on the perimeter sidewall, and wherein depositing the second metal layer comprises plating the second metal layer on the first metal layer. In certain embodiments, depositing the sidewall connector comprises forming an electrically conductive via through the submount and dicing the submount such that the electrically conductive via is positioned along the perimeter sidewall.

In another aspect, an LED package comprises: a submount comprising a first surface, a second surface, and a perimeter sidewall extending between the first surface and the second surface; a chip bonding pad on the first surface; an LED chip mounted to the chip bonding pad; a package bonding pad on the second surface; and a sidewall connector electrically coupling the chip bonding pad to the package bonding pad along the perimeter sidewall, the sidewall connector forming at least one half via along the perimeter sidewall. In certain embodiments, the sidewall connector comprises a first metal layer that is recessed into the perimeter sidewall and a second metal layer that laterally extends away from the perimeter sidewall. In certain embodiments, the second metal layer extends past the first metal to electrically contact a side surface of the chip bonding pad and a side surface of the package bonding pad. In certain embodiments, the LED chip covers at least 80% of an area of the first surface.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package according to aspects of the present disclosure.

FIG. 2 is a cross-sectional view of an LED device that includes multiple ones of the LED package of FIG. 1.

FIG. 3A is a cross-sectional view of the LED package of FIG. 1 at an initial fabrication step where the submount is formed as a larger panel with an array of the chip bonding pads and the package bonding pads.

FIG. 3B is a cross-sectional view of the LED package of FIG. 3A at a subsequent fabrication step where individual submounts are singulated from the panel of FIG. 3A.

FIG. 3C is a cross-sectional view of the LED package of FIG. 3B at a subsequent fabrication step after material for the first metal layer is formed on the sidewalls of each submount.

FIG. 3D is a cross-sectional view of the LED package of FIG. 3C at a subsequent fabrication step after another singulation step.

FIG. 3E is a cross-sectional view of the LED package of FIG. 3D at a subsequent fabrication step after the second metal layer is formed on the first metal layer on the perimeter sidewalls.

FIG. 3F is a cross-sectional view of the LED package of FIG. 3E at a subsequent fabrication step after LED chips are bonded to each submount.

FIG. 4 is a cross-sectional view of an LED package similar to the LED package of FIG. 1 with an alternative arrangement of the first and second metal layers for the sidewall connector.

FIG. 5A is a cross-sectional view of the LED package of FIG. 4 at an initial fabrication step where individual submounts are formed on the first temporary bond structure.

FIG. 5B is a cross-sectional view of the LED package of FIG. 5A at a subsequent fabrication step after a mask is provided to cover top surfaces of each submount.

FIG. 5C is a cross-sectional view of the LED package of FIG. 5B at a subsequent fabrication step after the first metal layer is formed.

FIG. 5D is a cross-sectional view of the LED package of FIG. 5C at a subsequent fabrication step after the second metal layer is formed.

FIG. 5E is a cross-sectional view of the LED package of FIG. 5D at a subsequent fabrication step after LED chips are bonded to each submount.

FIG. 6A is a top view of an LED package similar to the LED package of FIG. 1 at an initial fabrication step where the submount is formed on a temporary bond structure.

FIG. 6B is a top view of the LED package of FIG. 6A at a subsequent fabrication step after the sidewall connector is formed.

FIG. 6C is a top view of the LED package of FIG. 6B at a subsequent fabrication step after the mask of FIG. 6B is removed.

FIG. 6D is a top view of the LED package of FIG. 6C at a subsequent fabrication step after multiple LED chips are attached.

FIG. 6E is a top view of the LED package of FIG. 6D with superimposed dashed lines representing possible dicing lines for separating LED packages.

FIG. 6F is a cross-sectional view of the LED package taken along the sectional line 6F-6F of FIG. 6E.

FIG. 7A is a top view of an LED package similar to the LED package of FIGS. 6A to 6F for embodiments that further include a light-altering material formed along perimeter edges of the LED chips.

FIG. 7B is a cross-sectional view of the LED package taken along the sectional line 7B-7B of FIG. 7A.

FIG. 8A is a top view of an LED package similar to the LED package of FIGS. 6A to 6F for embodiments that further include a wavelength conversion element.

FIG. 8B is a cross-sectional view of the LED package taken along the sectional line 8B-8B of FIG. 8A.

FIG. 9A is a top view of an LED package similar to the LED package of FIG. 1 at an initial fabrication step where the first metal layer is formed as a number of vias that extend through the submount.

FIG. 9B is a top view of one LED package from FIG. 9A after singulation.

FIG. 9C is a top view of the LED package of FIG. 9B after formation of the second metal layer.

FIG. 9D is a cross-sectional view of the LED package of FIG. 9C with the addition of the LED chip.

FIG. 10A is a top view of a portion of an LED package that is similar to the LED package of FIGS. 9A to 9D at an initial fabrication step.

FIG. 10B is a top view of a portion of the LED package of FIG. 10A after singulation along the vertical dashed lines of FIG. 10A.

FIG. 10C is a top view of a portion of the LED package of FIG. 10B after the mask is formed.

FIG. 10D is a top view of a portion of the LED package of FIG. 10C after the second metal layer is formed.

FIG. 10E is a top view of a portion of the LED package of FIG. 10D for embodiments that further include another singulation step.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to submount structures in LED devices and related methods. Submount structures include submounts with sidewall connectors along perimeter sidewalls that electrically couple chip bonding pads on top submount surfaces to package bonding pads on submount bottom surfaces. LED devices include LED packages, such as chip-scale LED packages, with reduced footprints where electrically conductive paths are provided as one or more metal layers on the perimeter sidewalls. Exemplary methods include various sequences for depositing the sidewall connectors.

Before delving into specific details for aspects of the present disclosure, an overview of various elements that may be included in exemplary LED devices and packages is provided for context. An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from various material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

An LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

In certain embodiments, one or more lumiphoric materials may be provided as a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In some embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures may also include ceramic phosphor plates, phosphor-in-glass structures, and/or single crystal phosphors.

Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may be thinned before or after the patterning process is performed. In certain embodiments, wavelength conversion elements and cover structures may comprise a generally planar upper surface that corresponds to a light emission area of the LED package. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements. Wavelength conversion elements and cover structures may be attached to one or more LED chips using, for example, a layer of transparent adhesive such as silicone.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible submounts. By way of example, a flexible submount may comprise a polyimide, a polyethylene terephthalate (PET), and the like with electrically conductive traces. Flexible submounts allow improved bonding in a conformal manner to other surfaces that may not be entirely planar.

Aspects of the present disclosure are well suited for so-called chip-scale LED devices and/or LED packages where a submount structure is generally sized with similar dimensions as an LED chip mounted thereon. In such an arrangement, the submount may be formed with a same general footprint as the LED chip itself, thereby permitting miniaturization of the overall device size. As used herein, a chip-scale LED device or package may refer to a package structure having a package area that is up to 1.2 times an area of an included LED chip. Depending on which is larger, the package area may be defined by an area of the submount including sidewall connectors, or an area of the LED chip. In further aspects, additional elements, such as light-altering materials and/or wavelength conversion elements, may be included in the overall package area. In certain aspects, the LED chip may have a smaller area than the submount, the LED chip and the submount may have a same area, or the LED chip may have an area that is larger than the submount. In certain embodiments, the LED chip may cover at least 80%, or at least 90%, or at least 95% of an area of the submount. Such LED devices may be structured as surface mount devices where electrical contacts are on a bottom face of the submount for mounting and electrically connecting with another surface, such as a printed circuit board.

For such small device footprints, challenges exist in reliably routing the electrical connections from the LED chip to the bottom face of the submount. Conventional solutions include forming electrical vias through the submount to electrically connect the LED chip to the bottom side. However, such vias may exhibit blistering of material that leads to delamination of the LED chip when mounted thereon. Other approaches involve omitting the submount altogether, but such implementations have compromised mechanically stability and may fail at die attach and/or during product lifetime due to thermal cycling, leakage, and/or color shifting. Additional challenges for chip-scale LED devices include limited thermal dissipation. For example, in conventional chip-scale LED devices with electrical vias through submounts, the presence of the internal vias determines the location of the bottom side package bonding pads, leaving insufficient room to have a bottom side thermal pad. For chip-scale LED devices that omit a submount, only two bottom side package bonding pads are viable, since a neutral thermal pad would be mechanically floating and lack structural integrity.

Aspects of the present disclosure relate to chip-scale LED devices and/or LED packages that employ submount structures with improved mechanical stability, improved thermal dissipation, and provide improved coefficient of thermal expansion matching with mounting surfaces, such as boards and/or printed circuit boards. Submount structures are devoid of electrical vias within the material of the submount to avoid the problems of blistering and chip delamination. Instead, a series of electrical connections are provided along top faces, bottom faces, and sidewalls therebetween. The electrical connections on the sidewalls may be structured to vertically extend along the submount. In certain embodiments, the electrical connections on the sidewalls may extend to cover side surfaces of the electrical connections on the top and bottom sides or faces of the submount. In such a structure, the material of the submount may generally be intact for enhanced mechanical stability. Moreover, the LED chip may be mounted on and electrically coupled to the electrical connections on the sidewalls as well as those on the top face. The resulting LED device may also be mounted to another surface, such as that of a printed circuit board, with electrical interfaces that contact the bottom and optionally the sidewall connectors to provide a three-dimensional electrical interface. Additionally, since bottom side package bonding pads may be moved proximate to the sidewalls to contact the sidewall electrical connectors, additional area along the bottom side is available to accommodate a thermal pad.

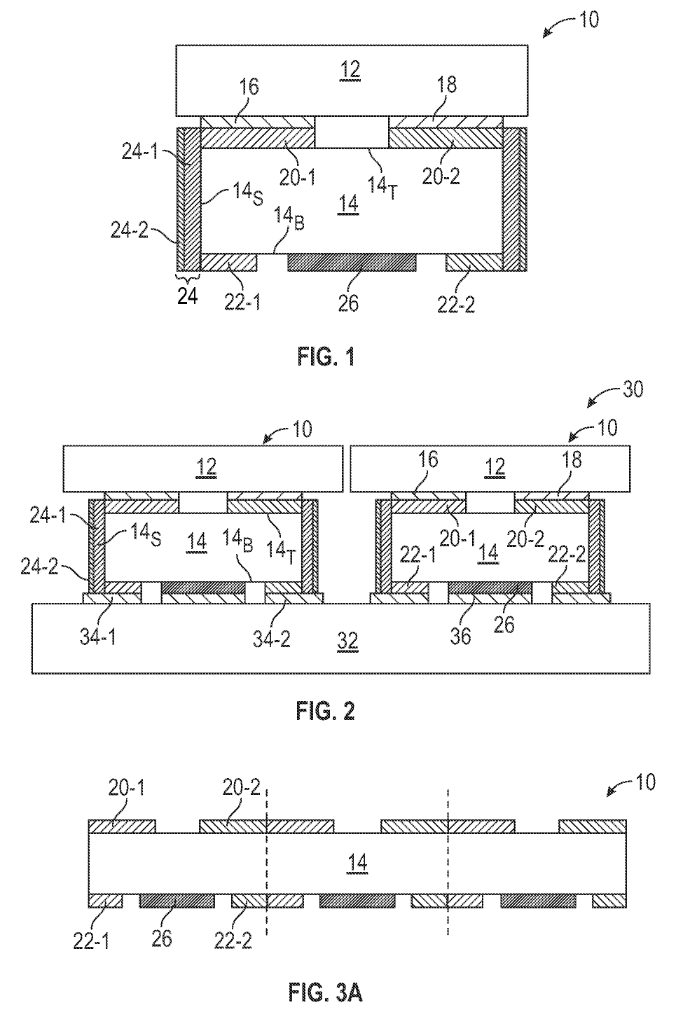

FIG. 1 is a cross-sectional view of an LED package 10 according to aspects of the present disclosure. The LED package 10 includes an LED chip 12 mounted to a submount 14. The LED chip 12 may include various chip structures described above, such as epitaxial layer structures with active LED structures configured to emit certain wavelengths of light. The LED chip 12 may or may not include a growth substrate that supports the epitaxial layer structures. In certain embodiments, the growth substrate may be removed after the LED chip 12 is attached to the submount 14. In other embodiments, the LED chip 12 may include the growth substrate in the final structure of the LED package 10. In FIG. 1, the LED chip 12 includes an anode pad 16 and a cathode pad 18 on a same side of the LED chip 12 for flip-chip mounting to the submount 14.

In certain embodiments, the submount 14 comprises a material with high thermal conductivity to assist with heat dissipation from the LED chip 12 during operation. For example, the submount 14 may comprise a ceramic material, such as alumina or aluminum nitride, among others. The submount 14 includes at least one chip bonding pad 20-1, 20-2 on a first surface (i.e., a top surface 14_{T}) positioned to receive the anode pad 16 or the cathode pad 18 of the LED chip 12. For flip-chip embodiments, two chip bonding pads 20-1, 20-2 are respectively positioned to receive the anode pad 16 and the cathode pad 18.

In certain embodiments, the LED package 10 embodies a chip-scale package where the submount 14 and the LED chip 12 have the same or similar lateral dimensions. For example, the LED chip 12 may cover at least 90% of the top surface 14_{T} of the submount 14, or the LED chip 12 may cover the entire top surface 14_{T}. In further embodiments the area of the LED chip 12 may be greater than an area of the top surface 14_{T} so that perimeter edges of the LED chip 12 extend past perimeter sidewalls 14_{S} of the submount 14. In certain embodiments, a lateral width of the LED chip 12 may be the same or larger than a lateral width of the submount 14 such that at least one perimeter edge of the LED chip 12 overhangs and extends past at least one perimeter sidewall 14_{S} of the submount 14.

In FIG. 1, the LED package 10 is structured as a surface mount package so that a second surface (i.e. a bottom surface 14_{B}) is positioned for mounting and electrically coupling to an external board or printed circuit board. As such, package bonding pads 22-1, 22-2 are positioned on the bottom surface 14_{B}. In conventional packages, electrical connections between the chip bonding pads 20-1, 20-2 and the package bonding pads 22-1, 22-2 may be made by way of electrically conductive vias that would extend through the material of the submount 14. However, such vias would be located directly beneath the LED chip 12 for chip-scale arrangements, thereby leading to potential chip delamination if such vias exhibit blistering of material. In other conventional packages that employ lead frames, thick metal leads are molded with a housing and the thick leads may be bent around the sides of the housing. However, the metal leads may form larger dimensions that may not be suitable for chip-scale LED packages. Moreover, the lead frames may not adhere as closely to housing sidewalls for use in chip-scale LED packages.

For the LED package 10, one or more sidewall connectors 24 are positioned to extend along the perimeter sidewalls 14_{S}of the submount 14 to provide electrical connections between the chip bonding pads 20-1, 20-2 and the package bonding pads 22-1, 22-2. Accordingly, no electrical connections are routed through the material of the submount 14 to avoid the blistering described above. The sidewall connectors 24 may embody one or more electrically conductive layers or coatings that are deposited or otherwise formed on the perimeter sidewalls 14_{S}. In certain embodiments, the sidewall connectors 24 may extend along and/or cover side surfaces of the chip bonding pads 20-1, 20-2 and/or the package bonding pads 22-1, 22-2. In this manner, the sidewall connectors 24 may bound at least one perimeter edge of the chip bonding pads 20-1, 20-2 and/or the package bonding pads 22-1, 22-2. In certain embodiments, the sidewall connector 24 may comprise a multiple layer metal structure formed on the perimeter sidewall 14_{S}. For example, the sidewall connector 24 may include a first metal layer 24-1 on the perimeter sidewall 14_{S}followed by a second metal layer 24-2 on the first metal layer 24-1 such that the first metal layer 24-1 is between the second metal layer 24-2 and the perimeter sidewall 14_{S}. In certain embodiments, the first metal layer 24-1 comprises a different metal than the second metal layer 24-2. For example, the first metal layer 24-1 may comprise a sintered metal paste, such as copper (Cu), tin-silver-copper (SAC) solder, or silver (Ag). By using a sintered metal paste, the first metal layer 24-1 may provide enhanced coverage of the perimeter sidewalls 14_{S} by covering and/or filling any irregularities on the surface of the perimeter sidewalls 14_{S}. In further embodiments, the second metal layer 24-2 may embody a plated metal that effectively covers and/or seals any irregularities in the first metal layer 24-1. The plated metal may include one or more of plated Ag, electroless nickel immersion gold (ENIG), and electroless nickel electroless palladium immersion gold (ENEPIG), among others. In certain implementations, the second metal layer 24-2 is optional and may be omitted if the first metal layer 24-1 is formed with sufficient thickness and structural integrity along the perimeter sidewalls 14_{S}. In certain embodiments, the second metal layer 24-2 may have a thickness that is less than a thickness of the first metal layer 24-1 relative to the perimeter sidewall 14_{S}. In contrast to thicker materials in conventional lead frame structures, a thickness of the sidewall connector 24 from the perimeter sidewall 14_{S} may be less than 35 microns (µm), such as in a range from 1 µm to 30 µm. In other embodiments, the thickness of the sidewall connector 24 may be extended to a range from 1 µm to 150 µm.

In certain embodiments, the chip bonding pads 20-1, 20-2 and the package bonding pads 22-1, 22-2 embody patterned metal traces on the submount 14. Moreover a thermal pad 26 may also be patterned on the bottom surface 14_{B} to provide additional thermal dissipation during use. In certain embodiments, the thermal pad 26 is electrically isolated from the LED chip 12. The resulting LED package 10 may embody a chip-scale package where electrically conductive paths are formed on exterior surfaces of the submount 14. The submount 14 may form a continuously solid material that provides mechanical support for the LED chip 12 while also providing enhanced heat dissipation by itself or optionally with the inclusion of the thermal pad 26. Moreover, the size of the thermal pad 26 may not be limited to avoid internal submount vias associated with conventional devices.

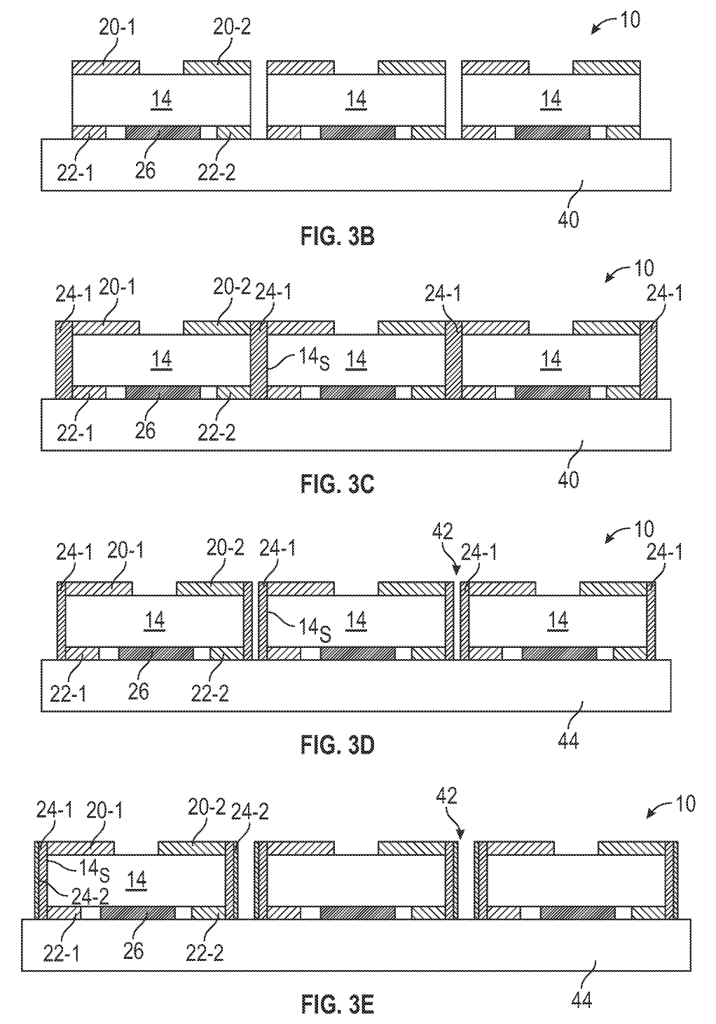

FIG. 2 is a cross-sectional view of an LED device 30 that includes multiple ones of the LED package 10 of FIG. 1. As illustrated in FIG. 2, the LED chip 12 of each LED package 10 is sized to laterally overhang and extend past the perimeter sidewalls 14_{S} of each corresponding submount 14. Such an arrangement advantageously permits the LED chips 12 to be positioned as close as possible to each other while still leaving suitable spacing for mounting the package bonding pads 22-1, 22-2 to a board 32. The board 32 may embody a printed circuit board for various embodiments where the device 30 represents a portion of an LED fixture, an LED module, or an LED display. The board 32 may have corresponding electrical traces 34-1, 34-2 positioned to receive the package bonding pads 22-1, 22-2. For embodiments where one or more of the LED packages 10 include the thermal pad 26, one or more corresponding traces 36 of the board 32 may be thermally coupled to the thermal pad 26. As illustrated, the electrical traces 34-1, 34-2 may be separated by a lateral spacing that is greater than a lateral spacing between the LED chip 12. Accordingly, the package bonding pads 22-1, 22-2 may be mounted to the electrical traces 34-1, 34-2 with reduced instances of shorting, while the LED chips 12 may be positioned as close as possible to each other or even touching. For embodiments where the LED chips 12 are structured to provide a same emission wavelength and/or color, the reduced spacing may reduce dark boundaries between the LED chips 12 and provide the appearance of a larger emitting surface. For embodiments where the LED chips 12 provide different emission wavelengths, such as red, green, and blue for LED displays, the reduced spacing between the LED chips 12 may provide increased pixel density.

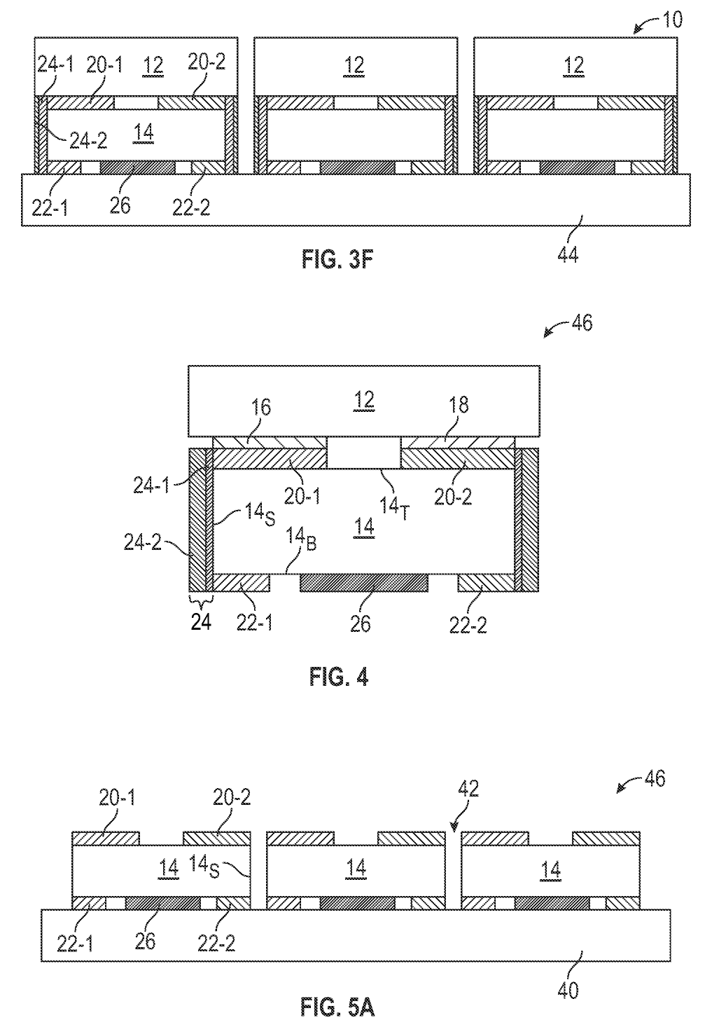

FIGS. 3A to 3F represent various fabrication steps for forming the LED package 10 of FIG. 1. FIG. 3A is a cross-sectional view of the LED package 10 at an initial fabrication step where the submount 14 is formed as a larger panel with an array of the chip bonding pads 20-1, 20-2 and the package bonding pads 22-1, 22-2. Superimposed vertical dashed lines are provided to represent dicing lines. For embodiments with the thermal pad 26, a corresponding array of the thermal pads 26 may also be provided.

FIG. 3B is a cross-sectional view of the LED package 10 of FIG. 3A at a subsequent fabrication step where individual submounts 14 are singulated from the panel of FIG. 3A. In certain embodiments, the submounts 14 may be supported by a first temporary bond structure 40. Singulation for the individual submounts 14 may include mechanical dicing such as sawing.

FIG. 3C is a cross-sectional view of the LED package 10 of FIG. 3B at a subsequent fabrication step after material for the first metal layer 24-1 is formed on the perimeter sidewalls 14_{S} of each submount 14. In certain embodiments, the material of the first metal layer 24-1 may embody a paste, or solder paste, that is formed to fill cracks and crevices between each submount 14. The material of the first metal layer 24-1 may be dispensed on the first temporary bond structure 40 with an amount and pressure that effectively fills the spaces between the submount 14 and covers the perimeter sidewalls 14_{S}. After filling, a heating or reflow temperature may be applied that solidifies and/or sinters the first metal layer 24-1 in place. In certain embodiments, the first metal layer 24-1 may be referred to as a sintered metal layer.

FIG. 3D is a cross-sectional view of the LED package 10 of FIG. 3C at a subsequent fabrication step after another singulation step. After the reflow and/or sintering step of FIG. 3C, the individual submounts 14 may be effectively joined together by the first metal layer 24-1. The second singulation step may be performed through the first metal layer 24-1 to provide separation between the individual submounts 14. As illustrated, openings 42 are formed through the first metal layer 24-1. The singulation step of FIG. 3D may also be performed by mechanical dicing. In certain embodiments, the singulation step is performed after a second temporary bond structure 44 is formed to replace the first temporary bond structure 40 of FIG. 3C. The second temporary bond structure 44 may comprise a more flexible material suitable for a subsequent stretching step. In other embodiments, it may not be necessary to replace the first temporary bond structure 40 of FIG. 3C.

FIG. 3E is a cross-sectional view of the LED package 10 of FIG. 3D at a subsequent fabrication step after the second metal layer 24-2 is formed on the first metal layer 24-1 on the perimeter sidewalls 14_{S}. In certain embodiments, the second temporary bond structure 44 (or the first temporary bond structure 40 if not replaced) is stretched to create greater separation and larger openings 42. In certain embodiments, an optional cleaning step may be performed to clean up singulation residue along the first metal layer 24-1 before the second metal layer 24-2 is formed. The second metal layer 24-2 may be plated within the openings 42 to effectively cover and/or seal any remaining irregularities of the first metal layer 24-1.

FIG. 3F is a cross-sectional view of the LED package 10 of FIG. 3E at a subsequent fabrication step after LED chips 12 are bonded to each submount 14. After the LED chips 12 are mounted, the second temporary bond structure 44 may be removed to provide multiple ones of the LED package 10 of FIG. 1. For illustrative purposes, the anode pad 16 and the cathode pad 18 of FIG. 1 are omitted for each LED chip 12. It is understood that the anode pad 16 and the cathode pad 18 are present for flip-chip embodiments in a manner described above for FIG. 1. Moreover, the width of each LED chip 12 relative to the submount 14 may be the same as described above for FIG. 1 and/or for FIG. 2.

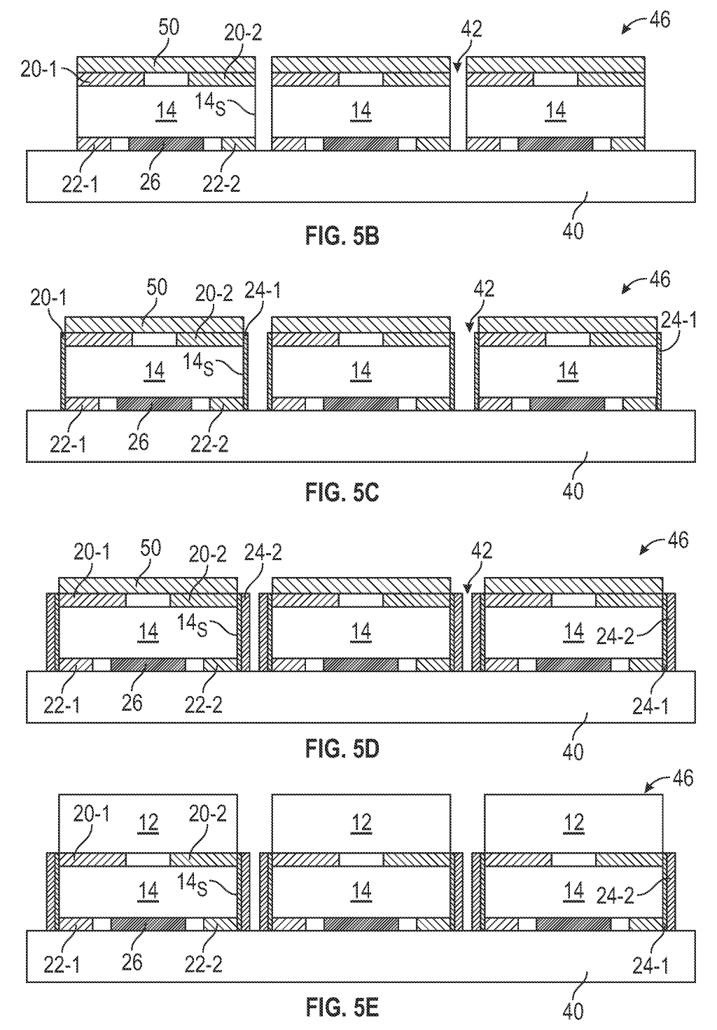

FIG. 4 is a cross-sectional view of an LED package 46 similar to the LED package 10 of FIG. 1 with an alternative arrangement of the first and second metal layers 24-1, 24-2 for the sidewall connector 24. In certain embodiments, the first metal layer 24-1 may form a seed metal layer for the second metal layer 24-2. In this regard, the first metal layer 24-1 may have a thickness that is less than a thickness of the second metal layer 24-2 relative to the perimeter sidewalls 14_{S}. The first metal layer 24-1 may embody a thin layer that is sputtered along the perimeter sidewalls 14_{S}, and the second metal layer 24-2 may embody a plated layer, such as an electroplated layer, that is subsequently formed.

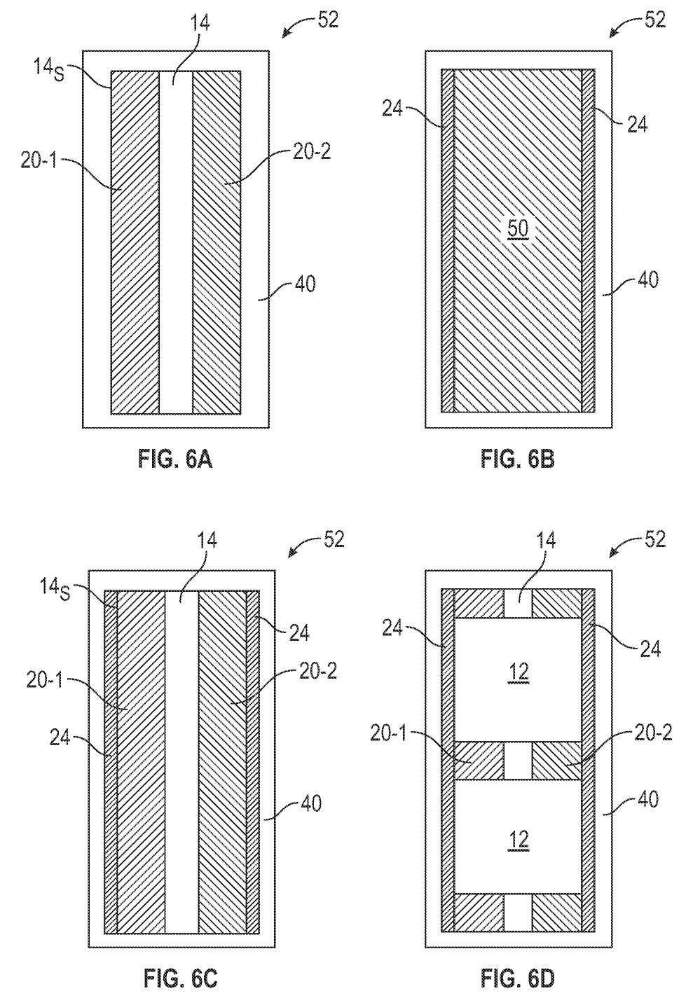

FIGS. 5A to 5E represent various fabrication steps for forming the LED package 46 of FIG. 4. FIG. 5A is a cross-sectional view of the LED package 46 at an initial fabrication step where individual submounts 14 are formed on the first temporary bond structure 40. In certain embodiments, the fabrication step illustrated by FIG. 5A is similar to the fabrication step for the LED chip 10 as illustrated by FIG. 3B. For embodiments with the thermal pad 26, a corresponding array of the thermal pads 26 may also be provided.

FIG. 5B is a cross-sectional view of the LED package 46 of FIG. 5A at a subsequent fabrication step after a mask 50 is provided to cover top surfaces of each submount 14. The mask 50 may serve to protect top surfaces of the chip bonding pads 20-1, 20-2 of each submount 14.

FIG. 5C is a cross-sectional view of the LED package 46 of FIG. 5B at a subsequent fabrication step after the first metal layer 24-1 is formed. The first metal layer 24-1 may be formed through the openings 42 and along the perimeter sidewalls 14_{S}. In certain embodiments, the first metal layer 24-1 may be sputtered to form a thin seed layer the readies the perimeter sidewalls 14_{S} for a plating or electroplating step.

FIG. 5D is a cross-sectional view of the LED package 46 of FIG. 5C at a subsequent fabrication step after the second metal layer 24-2 is formed. The second metal layer 24-2 may be formed by a plating step, such as electroplating. Since the first metal layer 24-1 forms a seed layer, the second metal layer 24-2 may effectively be plated on the first metal layer 24-1. The second metal layer 24-2 may be referred to as a plated layer and/or an electroplated layer.

FIG. 5E is a cross-sectional view of the LED package 46 of FIG. 5D at a subsequent fabrication step after LED chips 12 are bonded to each submount 14. Before die attach for the LED chips 12, the mask 50 in FIG. 5D is removed. After the LED chips 12 are mounted, the first temporary bond structure 40 may be removed to provide multiple ones of the LED package 46 of FIG. 4. For illustrative purposes, the anode pad 16 and the cathode pad 18 of FIG. 4 are omitted for each LED chip 12. It is understood that the anode pad 16 and the cathode pad 18 are present for flip-chip embodiments in a manner described above for FIGS. 1 and 4. Moreover, the width of each LED chip 12 relative to the submount 14 may be the same as described above for FIG. 1 and/or for FIG. 2.

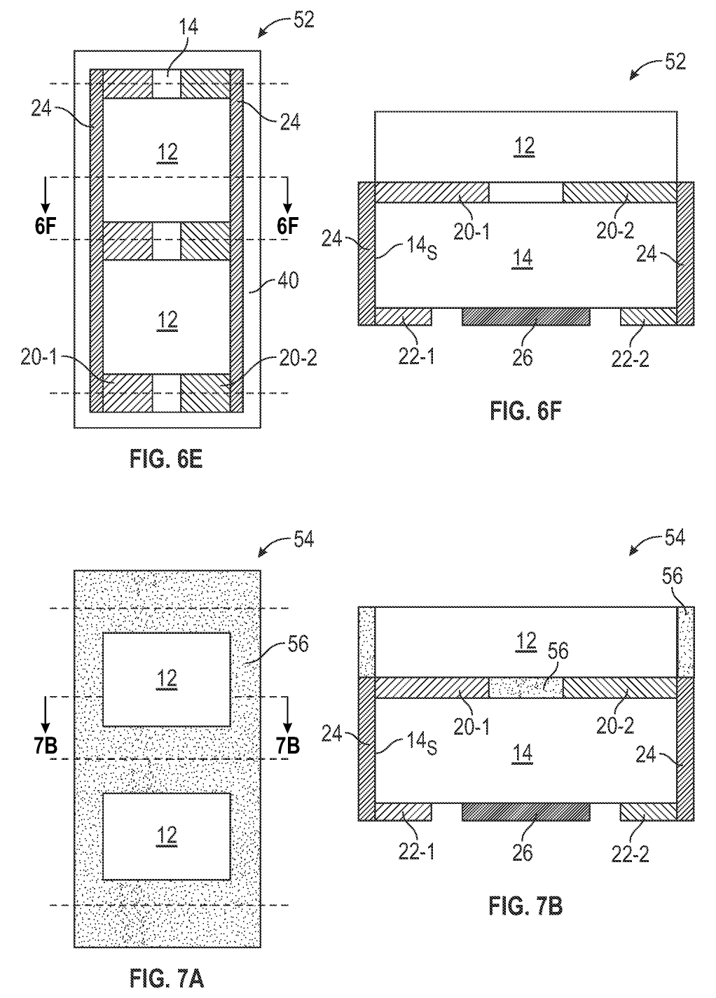

FIGS. 6A to 6F represent alternative fabrication steps for forming an LED package 52 that may be similar to the LED package 10 of FIG. 1 and/or the LED package 46 of FIG. 4. For illustrative purposes, the sidewall connectors 24 are illustrated as a single layer in FIGS. 6A to 6F. It is appreciated that the sidewall connectors 24 may include the arrangement of the first metal layer 24-1 and the second metal layer 24-2 as described above for either FIGS. 1 to 3F or FIGS. 4 to 5E.

FIG. 6A is a top view of the LED package 52 at an initial fabrication step where the submount 14 is formed on the first temporary bond structure 40. As illustrated, the submount 14 and corresponding chip bonding pads 20-1, 20-2 are formed with a larger area than previous embodiments. By way of example, the submount 14 and chip bonding pads 20-1, 20-2 are formed with an elongated shape, such as rectangular. By covering a larger area, the chip bonding pads 20-1, 20-2 may be structured for attaching multiple LED chips in bulk.

FIG. 6B is a top view of the LED package 52 of FIG. 6A at a subsequent fabrication step after the sidewall connector 24 is formed. In certain embodiments, the mask 50 as described above for FIG. 5D may be positioned to cover the submount 14 as illustrated in FIG. 6A, and the sidewall connectors 24 may be formed adjacent the mask 50. Alternatively, the sidewall connectors 24 may be formed without the mask 50 in a manner similar to the embodiments of FIGS. 3A to 3F.

FIG. 6C is a top view of the LED package 52 of FIG. 6B at a subsequent fabrication step after the mask 50 of FIG. 6B is removed. As illustrated, the sidewall connectors 24 may cover the perimeter sidewalls 14_{S} in an elongated manner. Depending on the shape of the mask 50 of FIG. 6B, the sidewall connectors 24 may even cover the entire perimeter sidewalls 14_{S} adjacent the chip bonding pads 20-1, 20-2.

FIG. 6D is a top view of the LED package 52 of FIG. 6C at a subsequent fabrication step after multiple LED chips 12 are attached. As illustrated, multiple LED chips 12 may be attached to the same pair of chip bonding pads 20-1, 20-2. For illustrative purposes, only two LED chips 12 are illustrated, however it is appreciated that many more LED chips 12 may be mounted to the same pair of chip bonding pads 20-1, 20-2 for bulk manufacturing.

FIG. 6E is a top view of the LED package 52 of FIG. 6D with superimposed dashed lines representing possible dicing lines for separating LED packages 52. In FIG. 6E, horizontal dashed lines are shown between each LED chip 12 to represent embodiments where each LED package 52 includes a single one of the LED chips 12. In other embodiments, the dicing lines may be reduced so that each LED package 52 includes more than one of the LED chips 12.

FIG. 6F is a cross-sectional view of the LED package 52 taken along the sectional line 6F-6F of FIG. 6E. As illustrated, the sidewall connectors 24 extend along the perimeter sidewalls 14_{S} to provide electrically conductive paths between the chip bonding pad 20-1 and the package bonding pad 22-1, and between the chip bonding pad 20-2 and the package bonding pad 22-2. In certain embodiments, the sidewall connectors 24 extend on and/or cover side surfaces of chip bonding pads 20-1, 20-2 and the package bonding pads 22-1, 22-2.

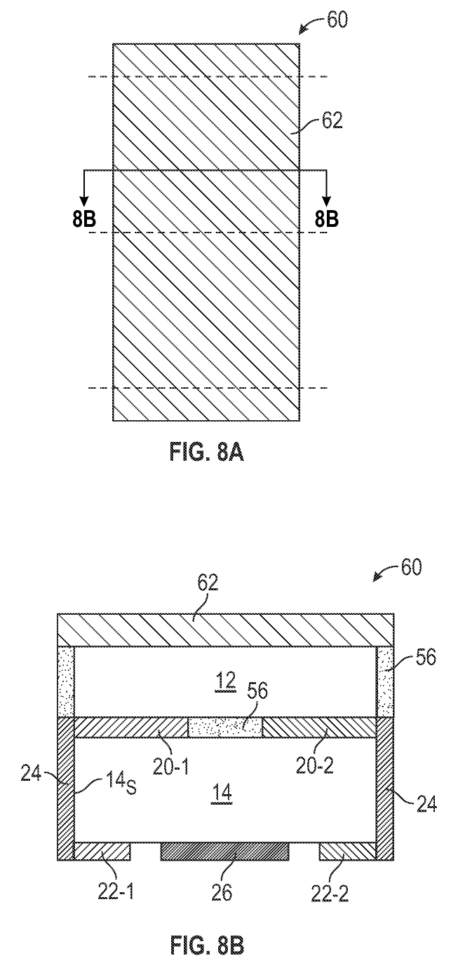

FIG. 7A is a top view of an LED package 54 similar to the LED package 52 of FIGS. 6A to 6F for embodiments that further include a light-altering material 56 formed along perimeter edges of the LED chips 12. The light-altering material 56 may embody a light-reflective material that effectively redirects lateral light from the LED chips 12 toward an intended emission direction. The light-altering material 56 may comprise light-reflective particles suspended in a binder, such as silicone. In one example, the light-altering material 56 forms a generally white color for light-reflection purposes. In other embodiments, the light-altering material 56 may exhibit light-absorbing characteristics for enhanced contrast between emission areas of the LED chips 12. In such embodiments, the light-altering material 56 may include light-absorbing particles suspended in a binder, such as silicone. In one example, the light-altering material 56 forms a generally dark or black color for enhanced contrast. As with FIG. 6E, superimposed dashed lines representing possible dicing lines are illustrated in FIG. 7A. During singulation, the light-altering material 56 may be singulated concurrently with the remainder of each LED package 54.

FIG. 7B is a cross-sectional view of the LED package 54 taken along the sectional line 7B-7B of FIG. 7A. As illustrated, the light-altering material 56 may cover perimeter edges of the LED chip 12. The light-altering material 56 may further reside on top surfaces of the sidewall connectors 24. In still further embodiments, the light-altering material 56 may extend between the LED chip 12 and the submount 14, such as filling spaces between the chip bonding pads 20-1, 20-2. If singulated concurrently with the remainder of the LED package 54, the light-altering material 56 may be coplanar with side surfaces of the sidewall connectors 24.

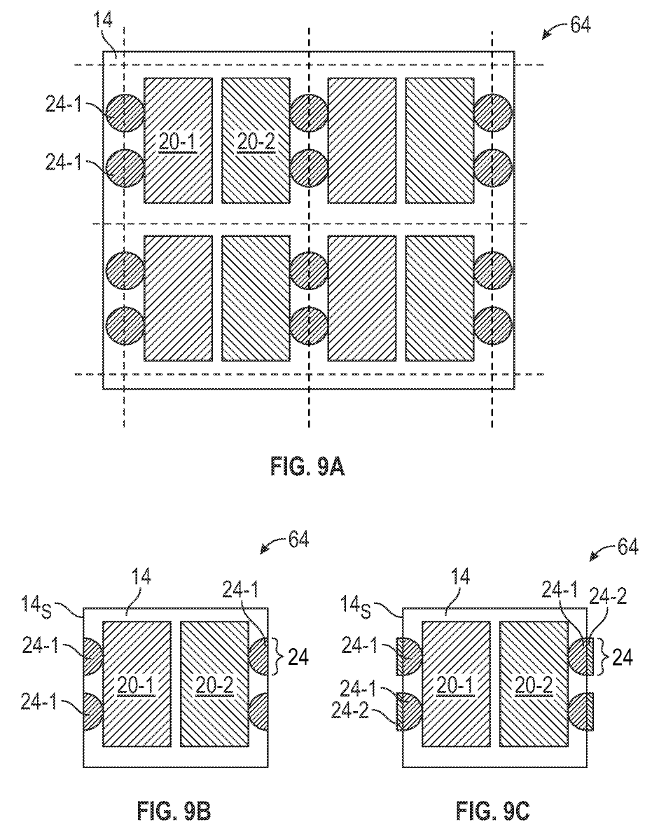

FIG. 8A is a top view of an LED package 60 similar to the LED package 52 of FIGS. 6A to 6F for embodiments that further include a wavelength conversion element 62. As with FIG. 6E, superimposed dashed lines representing possible dicing lines are illustrated in FIG. 8A. During singulation, the wavelength conversion element 62 may be singulated concurrently with the remainder of each LED package 60. The wavelength conversion element 62 may embody a lumiphoric material coating formed to cover the LED package 60. In other embodiments, the wavelength conversion element 62 may embody a lumiphoric material coating on a transparent support element, a phosphor-in-glass structure, a ceramic phosphor plate, or a single crystal phosphor.

FIG. 8B is a cross-sectional view of the LED package 60 taken along the sectional line 8B-8B of FIG. 8A. If singulated concurrently with the remainder of the LED package 60, the wavelength conversion element 62 may be coplanar with side surfaces of the light-altering material 56 and/or the sidewall connectors 24. In certain embodiments, the wavelength conversion element 62 is positioned on both the LED chip 12 and the light-altering material 56. In still further embodiments, the wavelength conversion element 62 directly contacts both the LED chip 12 and the light-altering material 56.

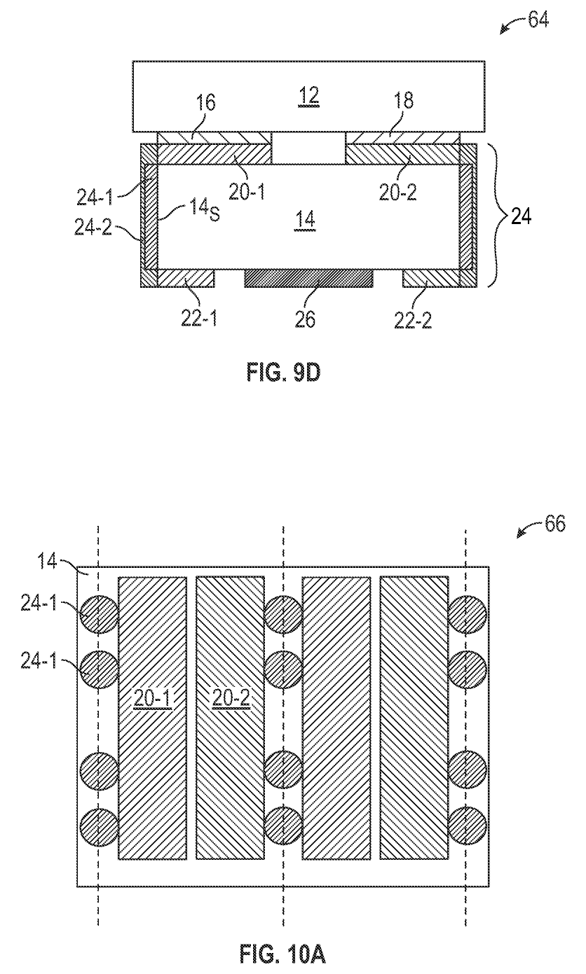

FIGS. 9A to 9D represent an LED package 64 similar to the LED package 10 of FIG. 1 for embodiments where the sidewall connectors 24 formed by the first metal layer 24-1 and/or the second metal layer 24-2 extend on only a portion of the perimeter sidewalls 14_{S}of the submount 14.

FIG. 9A is a top view of the LED package 64 at an initial fabrication step where the first metal layer 24-1 is formed as a number of vias that extend through the submount 14. To provide the first metal layer 24-1 in this manner, a number of through-holes are formed in the submount 14 that are subsequently filled with material of the first metal layer 24-1. A number of superimposed dashed lines are provided horizontally and vertically to represent dicing lines for each LED package 64. As illustrated, the vias of the first metal layer 24-1 may be formed to straddle the dicing lines so that when singulated, a portion of one via of the first metal layer 24-1 may be formed on neighboring LED packages 64. That is, when the submount 14 is singulated, the separation lines intersect and separate individual vias of the first metal layer 24-1.

FIG. 9B is a top view of one LED package 64 from FIG. 9A after singulation. As illustrated, a portion each via of the first metal layer 24-1 is provided on the perimeter sidewalls 14_{S} at opposing sides of the chip bonding pads 20-1, 20-2. For circular via shapes, the resulting first metal layer 24-1 may form a half circular shape or a half via after singulation. The first metal layer 24-1 may extend into the submount 14 from the perimeter sidewalls 14_{S}. In certain embodiments, the side surface of each portion of the first metal layer 24-1 is coplanar with the perimeter sidewalls 14_{S} of the submount 14. For illustrative purposes, two portions of the first metal layer 24-1 are illustrated on each perimeter sidewall 14_{S}; however, the principles described are applicable to any number of portions of the first metal layer 24-1 on each perimeter sidewall 14_{S}, including a single portion or half via. In certain embodiments, the first metal layer 24-1 as formed by one or more half vias may form one or more sidewall connectors 24. In other embodiments, the sidewall connector 24 may embody a multiple layer structure and the first metal layer 24-1 is only one of the metal layers.

FIG. 9C is a top view of the LED package 64 of FIG. 9B after formation of the second metal layer 24-2. In certain embodiments, the second metal layer 24-2 may be plated on the portions or half vias of the first metal layer 24-1. Accordingly, the second metal layer 24-2 may laterally extend slightly away from the perimeter sidewall 14_{S} while the first metal layer is recessed within the submount 14. The second metal layer 24-2 may be selectively plated on the first metal layer 24-1, and the resulting combination of the first and second metal layers 24-1, 24-2 form one or more sidewall connectors along each perimeter sidewall 14_{S}. The second metal layer 24-2 may thicken up the metal for each sidewall connector 24, particularly covering any irregularities from dicing of the first metal layer 24-1.

FIG. 9D is a cross-sectional view of the LED package 64 of FIG. 9C with the addition of the LED chip 12. Since the first metal layer 24-1 is initially formed as a through via within the submount 14, the first metal layer 24-1 may only cover the perimeter sidewalls 14_{S} of the submount 14 after singulation. However, the second metal layer 24-2 is formed after singulation and may thereby cover the first metal layer 24-1 and further extend to electrically contact side surfaces of the chip bonding pads 20-1, 20-2 and side surfaces of the package bonding pads 22-1, 22-2.

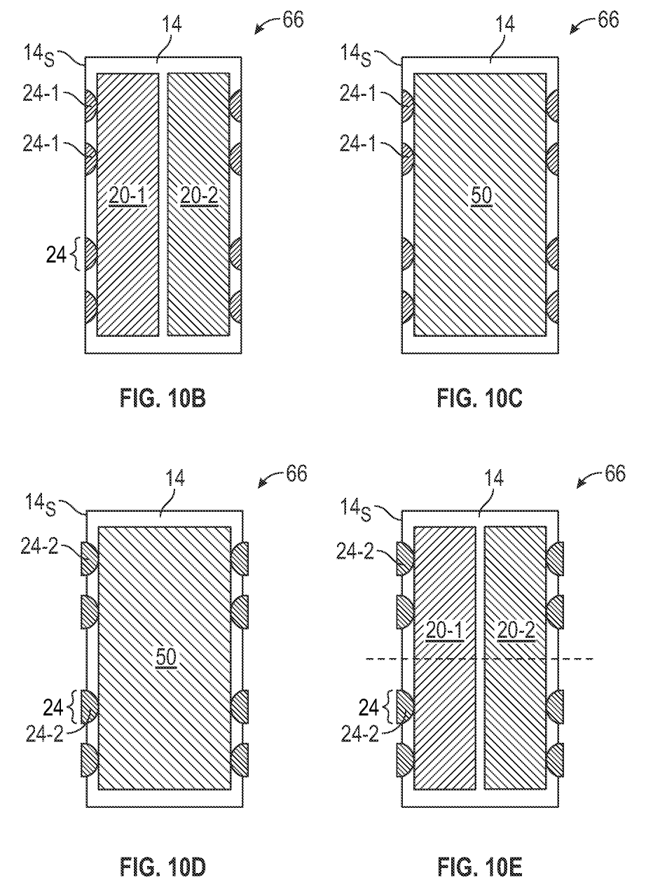

FIGS. 10A to 10E are top views of a portion of an LED package 66 that is similar to the LED package 64 of FIGS. 9A to 9D. FIGS. 10A to 10E represent various fabrication steps for forming the sidewall connector 24 as one or more discontinuous regions along each perimeter sidewall 14_{S}. In certain embodiments, the one or more discontinuous regions form electrically conductive half vias as described above for FIGS. 9A to 9D.

FIG. 10A is a top view of a portion of an LED package 66 that is similar to the LED package 64 of FIGS. 9A to 9D at an initial fabrication step. Vertical dashed lines are superimposed to represent dicing or singulation lines. In a similar manner as described above for FIG. 9A, the first metal layer 24-1 is formed as a number of vias that extend through the submount 14, and the vias are positioned to intersect the dicing lines.

FIG. 10B is a top view of a portion of the LED package 66 of FIG. 10A after singulation along the vertical dashed lines of FIG. 10A. As illustrated, the resulting first metal layer 24-1 may form a half circular shape or a half via after singulation. The first metal layer 24-1 may extend into the submount 14 from the perimeter sidewalls 14_{S} in a similar manner as described above for FIG. 9B.

FIG. 10C is a top view of a portion of the LED package 66 of FIG. 10B after the mask 50 is formed. The mask 50 is formed to cover top surfaces of the chip bonding pads 20-1, 20-2 of FIG. 10B while leaving the first metal layer 24-1 uncovered.

FIG. 10D is a top view of a portion of the LED package 66 of FIG. 10C after the second metal layer 24-2 is formed. The second metal layer 24-2 may be plated on the first metal layer 24-1 of FIG. 10C, thereby covering sides surfaces and top surfaces thereof. In this regard, the second metal layer 24-2 may laterally extend from the perimeter sidewalls 14_{S} of the submount 14 and also cover top and bottom surfaces of the underlying first metal layer 24-1 of FIG. 10C in a similar manner as illustrated in the cross-sectional view of FIG. 9D.

FIG. 10E is a top view of a portion of the LED package 66 of FIG. 10D for embodiments that further include another singulation step. A horizontal dashed line is superimposed in FIG. 10E to represent another singulation line for separating the submount 14 further. Each resulting LED package 66 may have the same or similar structure as illustrated for the LED package 64 of FIG. 9D.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package, comprising:
a submount comprising a first surface, a second surface, and a perimeter sidewall extending between the first surface and the second surface;
a chip bonding pad on the first surface;
an LED chip mounted to the chip bonding pad, the LED chip covering at least 80% of an area of the first surface;
a package bonding pad on the second surface; and
a sidewall connector electrically coupling the chip bonding pad to the package bonding pad along the perimeter sidewall.

2. The LED package of claim 1, wherein a lateral width of the LED chip is at least the same as a lateral width of the submount.

3. The LED package of claim 2, wherein the lateral width of the LED chip is greater than the lateral width of the submount.

4. The LED package of claim 1, wherein the sidewall connector extends on a side surface of the chip bonding pad and on a side surface of the package bonding pad.

5. The LED package of claim 1, wherein the sidewall connector comprises a first metal layer on the perimeter sidewall and a second metal layer on the first metal layer.

6. The LED package of claim 5, wherein the first metal layer comprises a sintered metal and the second metal layer comprises a plated metal.

7. The LED package of claim 5, wherein the first metal layer comprises a seed layer and the second metal layer comprises a plated metal.

8. The LED package of claim 1, further comprising a light-altering material on perimeter edges of the LED chip.

9. The LED package of claim 8, further comprising a wavelength conversion element on the LED chip and on the light-altering material.

10. The LED package of claim 1, wherein the sidewall connector forms at least one half via along the perimeter sidewall.

11. The LED package of claim 10, wherein the sidewall connector comprises a first metal layer that extends along the perimeter sidewall and a second metal layer on the first metal layer, wherein the second metal layer extends past the first metal to electrically contact a side surface of the chip bonding pad and a side surface of the package bonding pad.

12. The LED package of claim 1, further comprising a thermal pad on the second surface of the submount, wherein the thermal pad is electrically isolated from the LED chip.

13. A method for forming a light-emitting diode (LED) package, the method comprising:
providing a submount comprising a first surface, a second surface, and a perimeter sidewall extending between the first surface and the second surface;
forming a chip bonding pad on the first surface and a package bonding pad on the second surface;
depositing a sidewall connector on the perimeter sidewall, the sidewall connector electrically coupling the chip bonding pad to the package bonding pad along the perimeter sidewall; and
attaching an LED chip to the chip bonding pad, the LED chip covering at least 80% of an area of the first surface.

14. The method of claim 13, wherein depositing the sidewall connector comprises depositing a first metal layer on the perimeter sidewall and depositing a second metal layer on the first metal layer.

15. The method of claim 14, wherein depositing the first metal layer comprises dispensing the first metal layer followed by heating the first metal layer to solidify the first metal layer, and wherein depositing the second metal layer comprises plating the second metal layer on the first metal layer.

16. The method of claim 14, wherein depositing the first metal layer comprises depositing the first metal layer as a seed layer on the perimeter sidewall, and wherein depositing the second metal layer comprises plating the second metal layer on the first metal layer.

17. The method of claim 13, wherein depositing the sidewall connector comprises forming an electrically conductive via through the submount and dicing the submount such that the electrically conductive via is positioned along the perimeter sidewall.

18. A light-emitting diode (LED) package, comprising:
a submount comprising a first surface, a second surface, and a perimeter sidewall extending between the first surface and the second surface;
a chip bonding pad on the first surface;
an LED chip mounted to the chip bonding pad;
a package bonding pad on the second surface; and
a sidewall connector electrically coupling the chip bonding pad to the package bonding pad along the perimeter sidewall, the sidewall connector forming at least one half via along the perimeter sidewall.

19. The LED package of claim 18, wherein the sidewall connector comprises a first metal layer that is recessed into the perimeter sidewall and a second metal layer that laterally extends away from the perimeter sidewall.

20. The LED package of claim 19, wherein the second metal layer extends past the first metal to electrically contact a side surface of the chip bonding pad and a side surface of the package bonding pad.

21. The LED package of claim 18, wherein the LED chip covers at least 80% of an area of the first surface.
